(19) United States
(12) Patent Application Publication
(10) Pub. No.: US 2008/0124670 A1
(43) Pub. Date: May 29, 2008

(54) Inductively heated trap

(76) Inventor: Frank Jansen, San Jose, CA (US)

Correspondence Address: THE BOC GROUP, INC., 575 MOUNTAIN AVENUE, MURRAY HILL, NJ, 07974-2064, US

(21) Appl. No.: 11/605,793

(22) Filed: Nov. 29, 2006

(51) Int. Cl. F24H 3/02; C23C 16/00

(52) U.S. Cl. 432/29; 118/724

(57) ABSTRACT

An inductively heated trap for treating and removing compounds from an exhaust stream. More particularly, a method and apparatus for inductively heating a trap installed in the exhaust stream of a semiconductor process, wherein the trap decomposes exhaust gas compounds prior to entering a vacuum exhaust pump. The trap treats precursor compounds, such as metal organic and halide compounds, by thermally radicalizing the precursor vapors prior to entering the vacuum pump. The trap may be used in a variety of applications including atomic layer deposition, chemical vapor deposition and perfluorocarbon abatement.

### FIELD OF THE INVENTION

The invention relates to a heated trap for treating and removing compounds from an exhaust stream. More particularly, the present invention provides a method and apparatus for inductively heating a trap installed in the exhaust stream of a semiconductor process, wherein the trap decomposes exhaust gas compounds (e.g., metal-organic compounds) prior to entering the vacuum exhaust pump.

### BACKGROUND OF THE INVENTION

Atomic layer deposition (“ALD”) is a process during which very thin films are deposited onto a substrate within a process chamber. Individual precursor gases are sequentially pulsed into the process chamber and therein deposit onto the substrate (e.g., a semiconductor wafer). Only one precursor gas is introduced into the chamber at a time to prevent mixing of the gases. Each precursor gas reacts with the substrate to form an atomic layer related to that particular precursor.

To prevent the precursor gases from reacting with each other or in areas other than the target surface, an inert gas is introduced to purge the chamber between applications of the different precursor gases. Typically argon or nitrogen is used as a purge gas during ALD deposition processes.

In recent years and with the emergence of ALD as an important deposition process, the use of liquid metal-organic compounds as precursors has steadily grown. In order to use such metal-organic compounds in an ALD process, many of these precursors must first be vaporized. Vaporization typically occurs in a vaporizer mounted upstream from the process chamber. In the vaporizer a liquid precursor is heated under a reduced pressure, created by one or more vacuum pumps, to transform the liquid into a vapor of the same chemical composition.

Problems result, however, when a vaporized metal-organic precursor is exhausted from the process chamber and enters the vacuum pump. The vacuum pump compresses the unreacted precursor vapors causing them to condense and remain in the pump. When the next precursor gas is exhausted from the chamber it reacts with the residual condensate and it also condenses in the pump. Consequently, reactions between the alternating precursor gases and condensates may form solid particles or deposits within the pump that can substantially reduce pumping efficiency and ultimately result in a mechanical failure of the pump. In addition, such reactions may form corrosive compounds that erode the wetted materials of the pump and form particulates that may also lead to pump failure.

One solution to the above-mentioned problem is to prevent condensation of the precursor vapors by heating the pump. While this approach is suitable for some ALD processes (e.g., processes using water vapor, titanium tetrachloride, TEOS and the like), for other ALD processes heating the pump has the opposite and undesirable effect of plating the precursors within the pump mechanism.

Another approach is to condition the process exhaust so that the ALD exhaust gases stay in the gas phase despite the increased pressure in the pumping system. Typically fluorine gas or hydrogen gas is added to condition the exhaust stream prior to entering the pump. However, use of these gases has undesirable safety implications, the mitigation of which bears additional cost.

Yet another solution is to apply a plasma source to the exhaust gases. In one approach the plasma source chemically activates the secondary reactant gas stream. An example is the reaction of fluorine gas activated species such as atomic fluorine with the exhaust gas from a tungsten nitride (WN) barrier layer deposition process. In another approach, a plasma source removes materials by forcing the exhaust stream through a long plasma discharge channel, e.g., the commercial product Dry-Scrub. Both methods suffer from well-known drawbacks inherent in plasma-based technologies: 1) a plasma of a given type can only be created and sustained in a relatively narrow pressure regime (e.g., between 100 mTorr to 1 Torr for a diode plasma) yet often there is no control over the pressure in the exhaust line; 2) inductively coupled plasmas are not inherently self-starting and require a degree of capacitive coupling or an igniter and a means to check that the plasma is “ON”; and 3) plasmas are notoriously inefficient in the generation of chemically active species (i.e., 20-30%).

Thus, in view of the many drawbacks in the above-mentioned approaches for preventing adverse reactions in a vacuum pump, a new method and apparatus for eliminating such reactions is needed.

### SUMMARY OF THE INVENTION

An apparatus for treating an effluent gas from a process chamber prior to entering a vacuum pump comprising a housing wherein a portion of the housing comprises an insulator material; an inlet conduit adapted to pass the effluent gas from the process chamber to the housing; an outlet conduit adapted to pass treated effluent gas from the housing to the vacuum pump; a susceptor positioned within the housing proximate the insulator material; and an induction coil positioned externally to the housing proximate the insulator material.

A method of treating an effluent gas from a process chamber prior to entering a vacuum pump wherein a trap is positioned between the process chamber and the vacuum pump and an inlet conduit connects the process chamber to the trap and an outlet conduit connects the trap to the vacuum pump comprising activating the vacuum pump; activating an induction coil to heat a susceptor positioned within the trap wherein the effluent gas exits the inlet conduit, contacts the heated susceptor and decomposes; and exhausting byproducts of the decomposed gas through the outlet conduit.

### BRIEF SUMMARY OF THE DRAWINGS

FIG. 1a is a schematic representation of one embodiment of the apparatus according to the present invention.

FIG. 1b is a schematic representation of another embodiment of the apparatus according to the present invention.

FIG. 2 is a schematic representation of an induction coil.

FIG. 3a is a schematic representation of another embodiment of the apparatus according to the present invention.

FIG. 3b is a schematic representation of an embodiment of a bracket for supporting a susceptor according to the present invention.

FIG. 4 is a schematic representation of another embodiment of the apparatus according to the present invention.

### DETAILED DESCRIPTION

The present invention provides a method and apparatus for eliminating vapor condensation and reaction within a pump. Specifically, the inductively heated trap of the present invention treats precursor compounds (e.g., metal organic and halide compounds) from a low pressure exhaust stream by thermally radicalizing the precursor vapors prior to entering the pump. Although the invention may be used in a variety of applications (e.g., chemical vapor deposition, perfluorocarbon abatement, etc.), it will be described herein in the context of an atomic layer deposition (“ALD”) process involving metal-organic precursors. Notably, the present invention has a higher efficiency, larger capacity and lower cost than the other above-mentioned pre-pump exhaust conditioning devices.

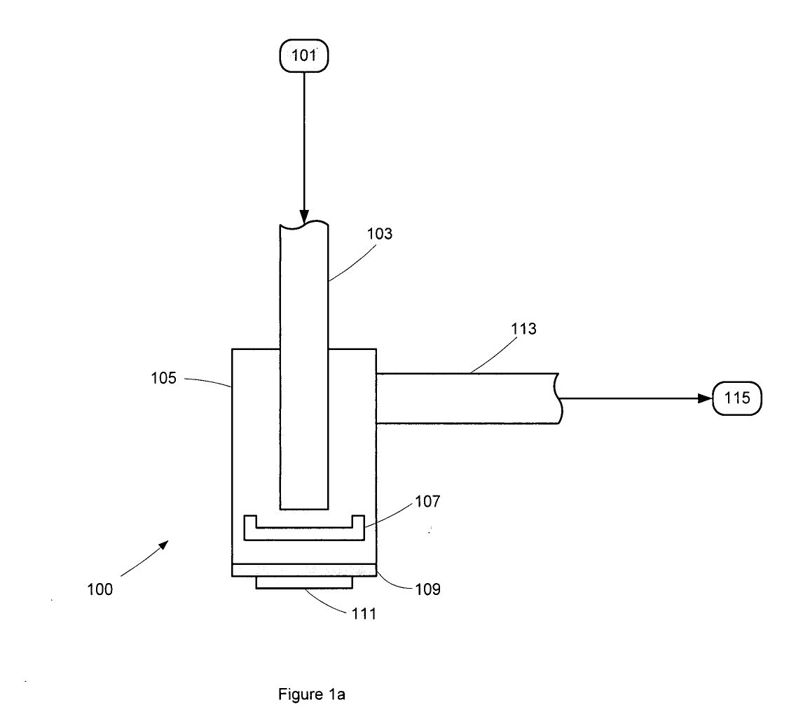

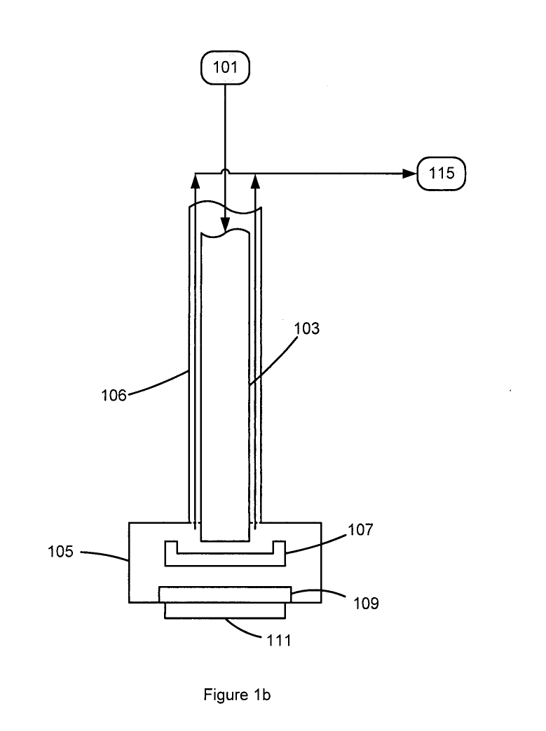

A first embodiment of an inductively heated trap 100 according to the present invention is shown in FIG. 1. Unreacted exhaust gases (e.g., WF₆, Al(CH₃), TiCl₄, Ta(OC₂H₅)₅) flow from the process chamber 101 through an exhaust conduit 103 (e.g., a stainless steel conduit). The exhaust conduit 103 extends into a trap housing 105 that is welded or clamped to conduit 103. The trap housing 105 is preferably constructed of stainless steel or other non-corrosive metal. A vacuum exhaust conduit 113 is also connected to the trap housing 105 and permits one or more vacuum pumps 115 (e.g., turbomolecular pumps) to withdraw gas from both the process chamber 101 and the trap housing 105.

In another embodiment, the process exhaust conduit 103 may be positioned within the vacuum exhaust conduit 113 in an annular arrangement as shown in FIG. 1b. In this embodiment, the treated exhaust gas flows through the annular space between the conduits 103, 113 and to the one or more pumps.

In both embodiments, the end of the process chamber exhaust conduit 103 is positioned above a heated susceptor 107 so that exhaust gas exiting the exhaust conduit 103 may come into contact with the susceptor 107. The susceptor 107 is preferably constructed of a carbon material such as high density graphite or other material having a specific resistivity between about 5×10⁻⁵ Ω-cm and about 1×10⁻³ Ω-cm. The optimal distance between the end of the conduit 103 and the susceptor 107 is dependent upon the flow rate of the exhaust gases exiting the chamber 111. Such positioning will be discussed in more detail below. The susceptor 107 may be a flat plate and preferably includes side walls extending vertically from the plate (see FIG. 1).

At least a portion of the trap housing 105, for example at least a portion of the base 109, is constructed of an insulator material such as a dielectric material. Suitable dielectric materials include glass, quartz, alumina, silicon nitride, silica, black glass and mullite or combinations thereof. In one embodiment, the susceptor 107 may be positioned above the insulator material 109 on brackets (not shown) extending from the side walls of the housing 105. In another embodiment the susceptor 107 may be positioned directly on the insulator material 109. In addition, the base 109 is preferably removable so that a used susceptor 107 may be removed from the trap housing 105 and replaced. In one embodiment, a vacuum tight seal is created, such as by positioning an o-ring (not shown) in a groove in the trap housing 105 and securely clamping the base 109 to the trap housing 105.

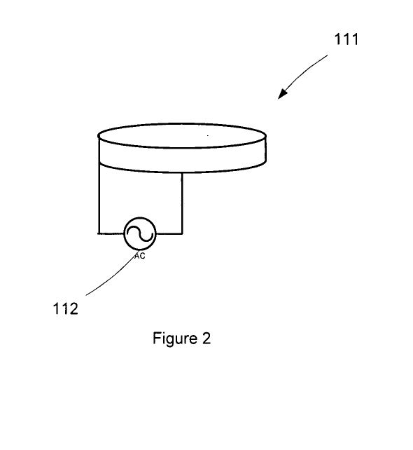

An induction coil 111 is positioned on or near the atmospheric side of the base 109 of the trap housing 105 as shown in FIG. 1. The induction coil 111 is preferably flat and of the same geometry as the susceptor 107 to optimize heating of the susceptor 107. An embodiment of the induction coil 111 is shown in FIG. 2. Preferably, the center of the induction coil 111 is aligned with both the center of the susceptor 107 and the center of the process exhaust conduit 103 in order to provide even heating of the susceptor 107 thereby optimizing thermal radicalization of the precursor gases. Power is supplied to the coil 111 with a high frequency A/C power source 112 (e.g., 1-2 kW and 1-25 kHz).

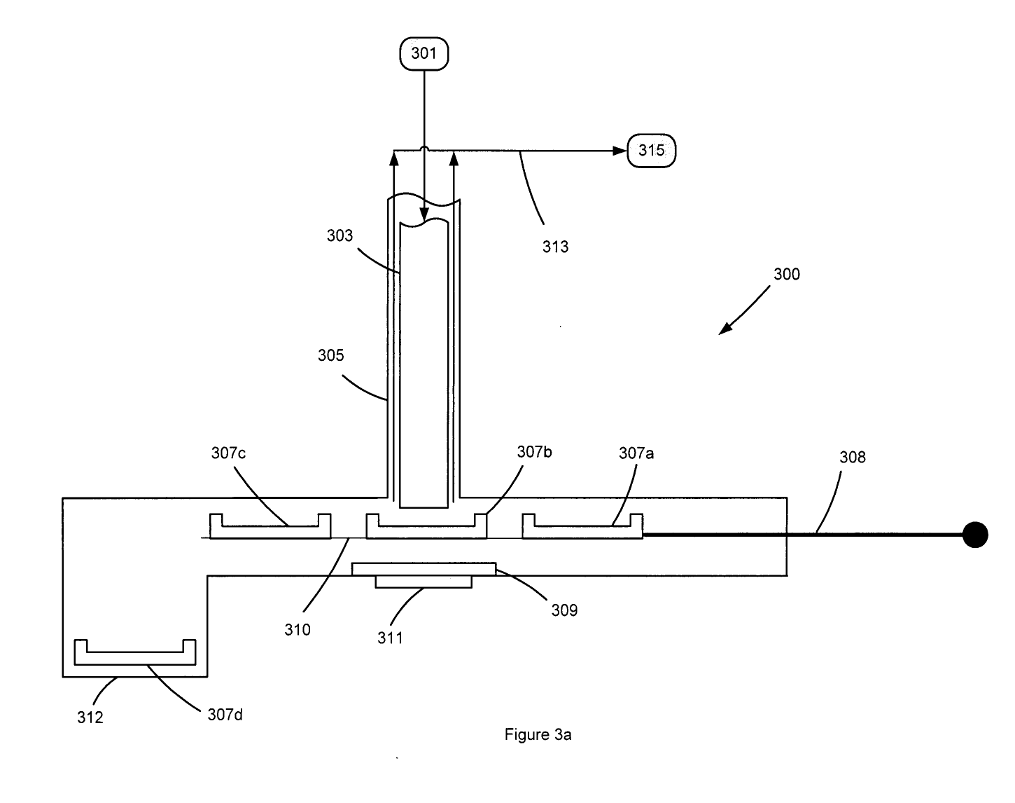

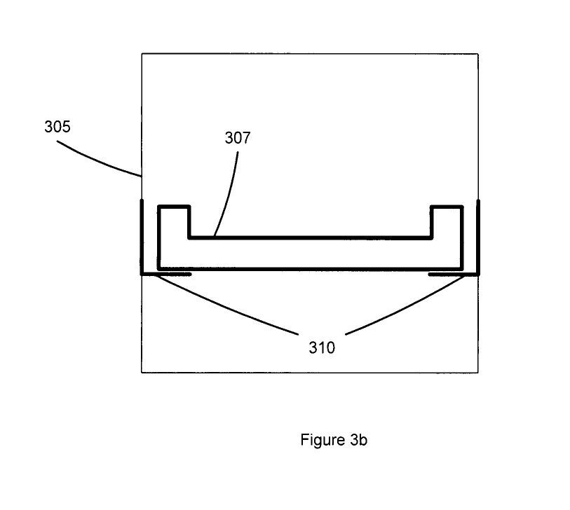

Another embodiment of a trap 300 according to the present invention is shown in FIG. 3. In this embodiment, the trap 300 contains multiple susceptors 307a, 307b, 307c each of which may be positioned beneath the exhaust conduit 303. Like the trap 100 of FIG. 1, trap 300 includes a trap housing 305 connected to a process exhaust conduit 303 and a vacuum exhaust conduit 313. The process exhaust conduit 303 receives unreacted precursor gas from a process chamber 301 and the one or more vacuum pumps 315 receive decomposed precursor gas from the vacuum exhaust conduit 313. In one embodiment, the process exhaust conduit 303 may be positioned within the vacuum exhaust conduit 313 in an annular arrangement to define an annular space between the conduits through which the decomposed precursor gas may flow to the one or more pumps 315.

As shown in FIG. 3, positioned beneath the process exhaust conduit 303 is a susceptor 307b that may be heated by induction coil 311. Like trap 100, at least a portion of the base of the trap housing 305 proximate to or above the induction coil 311 is constructed of an insulator material 309 such as glass, quartz, alumina, silicon nitride, silica, black glass and mullite or combinations thereof.

In one embodiment, the susceptors 307a, 307b, 307c are positioned on a pair of L-shaped brackets 310 connected to the inside walls of housing 305 as shown in FIG. 3b. The bracket is preferably constructed of an insulator material to minimize heat transfer between the heated susceptors 307 and the housing 305. A susceptor positioning means, such as push rod 308, may be used to advance a “used” susceptor from a position beneath the process exhaust conduit 303 to a storage area 312 while the housing 305 and system remain under vacuum. Simultaneously, the push rod 308 advances an “unused” susceptor to the position beneath the process exhaust conduit 303. For example, when susceptor 307b becomes substantially coated with decomposed precursor material, which may be indicated by a preset passage of time or by a sensor, an operator may push the rod to progress susceptor 307b from its position beneath the conduit 303 to the position of susceptor 307c. Simultaneously, susceptor 307a would move to the former position of susceptor 307b beneath the conduit 303 and susceptor 307c would move to storage area 312.

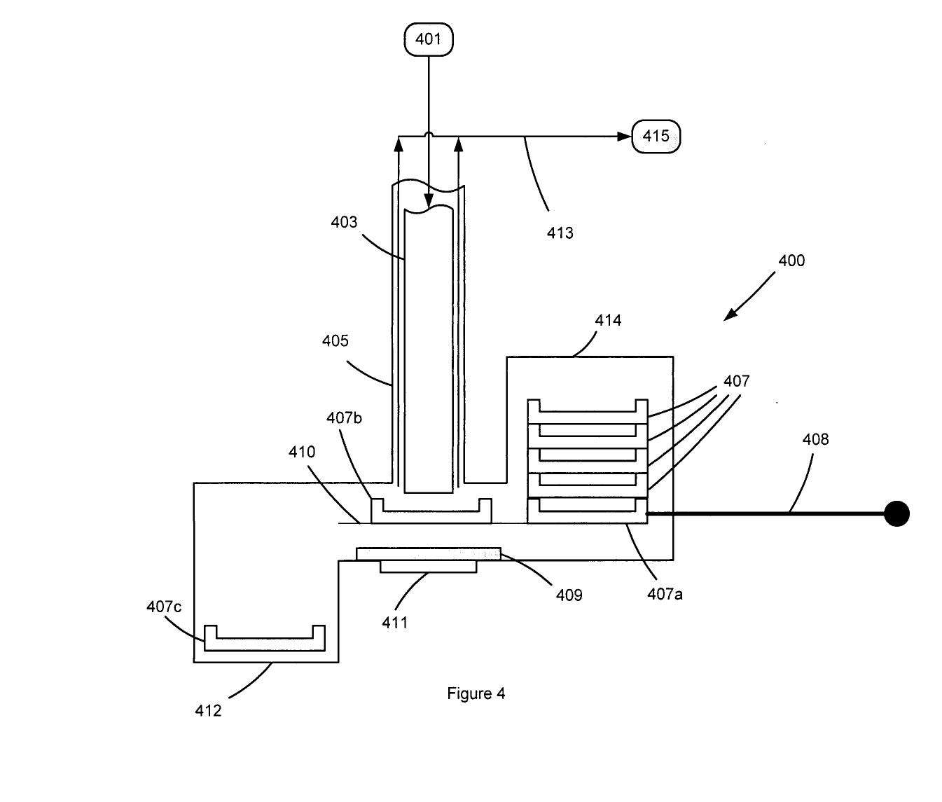

In another embodiment, shown in FIG. 4, the susceptor positioning means may be a reciprocating rod mechanism 408 to move a used, first susceptor 407b from beneath the conduit 403 to a storage area 412 and to move an unused, second susceptor 407a from a holding chamber 414 to the position beneath the conduit 403. This latter embodiment requires a smaller footprint than the embodiment shown in FIG. 3. In either embodiment, additional susceptors 407 may be stored in the storage chamber 414 until needed.

The traps 100, 300 and 400 may also be a part of a system. Such system may include a controller (not shown) connected to the process chamber 101, 301, 401 the A/C power source 112 and the one or more vacuum pumps 115, 315, 415. In addition, the controller may also control valves (not shown), such as gate valves, positioned within the system. For example, a gate valve may be positioned in the chamber exhaust conduit 103, 303, 403 between the housing 105, 305, 405 and the process chamber 101, 301, 401. Another gate valve may be positioned in the vacuum exhaust conduit 113, 313, 413 between the trap housing 105, 305, 405 and the process chamber 101, 301, 401. In embodiments 300 and 400, an additional gate valve may be positioned in the lower part of the trap housing 305, 405 to function as a sealing means to the housing 305, 405 to permit access to the susceptors 307, 407.

During operation of the system, the one or more vacuum pumps 115, 315, 415 maintain a high vacuum in the chamber 101, 301, 401 during the deposition process and simultaneously exhaust the chamber 101, 301, 401 and the trap 100, 300, 400. The one or more pumps 115, 315, 415 withdraw unreacted gas from the process chamber 101, 301, 401 through conduit 103, 303, 403. The flow rate and conductance of the gas through the conduit 103, 303, 403 is dependent upon the pump speed. As the gas exits the conduit 103, 303, 403 it comes into contact with the heated susceptor 107, 307, 407. The gate valves (not shown) in the exhaust conduits 103, 303, 403 and 113, 313, 413 remain open while the one or more pumps 115, 315, 415 withdraw gas through the conduits 103, 303, 403 and 113, 313, 413 during a deposition process.

The trap 100, 300, 400 must be configured to simultaneously maximize the conductance of the precursor gas through the conduit 103, 303, 403 and the probability that the precursor gas molecules will collide with the surface of the susceptor 107, 307, 407. To accomplish this, the gas preferably flows through the process exhaust conduit 103, 303, 403 at a high conductance (e.g., 1 to 50 slm) and in plug flow (i.e., where all portions of the precursor gas flow at the same velocity and in the same direction within the conduit 103, 303, 403). In addition, the susceptor 107, 307, 407 is positioned relative to the exhaust conduit 103, 303, 403 to increase the probability of the gas molecules colliding with the susceptor 107, 307, 407. Notably, prior to operation of the system, an operator may enter a specified value or range of values for the pump speed to ensure that the exhaust gas flows through the process exhaust conduit at a predetermined conductance to achieve plug flow.

The optimal distance between the susceptor 107, 307, 407 and the end of exhaust conduit 103, 303, 403 may vary for each process based upon the conductance of the gas through the conduit 103, 303, 403. The susceptor 107, 307, 407 should be positioned close enough to the end of the conduit 103, 303, 403 so that substantially all of the gas exiting the conduit 103, 303, 403 contacts the susceptor 107, 307, 407 while still in plug flow. If the susceptor 107, 307, 407 is positioned too far from the end of the conduit 103, 303, 403, the gas will disperse before contacting the susceptor 107, 307, 407 thereby flowing directly into the vacuum exhaust conduit 113, 313, 413. In addition, the susceptor 107, 307, 407 must also be positioned far enough away from the bottom of the conduit 103, 303, 403 so that as deposits build up on the susceptor 107, 307, 407 the conduit 103, 303, 403 does not become clogged within a short period of time (i.e., on the order of minutes). Preferably, the end of the conduit 103 is positioned at a height H above the susceptor 107 determined by the following equation: H>R/2 where R is the radius of the conduit 103, 303, 403. For example, an exhaust conduit that is 4 inches in diameter is preferably positioned approximately 1 inch above the susceptor 107, 307, 407.

During a deposition process, while the one or more vacuum pumps 113, 313, 413 are withdrawing unreacted precursor gas through conduit 103, 303, 403, the controller (not shown) sends a signal to the power source 112 causing an alternating voltage to be applied to the induction coil 111 311, 411. As a result, an alternating current is generated within the coil 111, 311, 411 thus producing in the surroundings an electromagnetic field having the same frequency as the current in the coil 111, 311, 411. The electromagnetic field passes through the base 109, 309, 409 of the trap housing 101, 301, 409 and induces in the susceptor 107, 307, 407 a current that flows against the resistivity of the susceptor material to produce heat by the Joule effect (i.e., P=I²R where P is power, I is current and R is resistance). The susceptor 107, 307, 407 is thus heated to a reaction temperature between about 400° C. and about 600° C. in a matter of seconds. Notably, even at temperatures much lower than this, all of the metal-organic compounds will decompose and form a solid film on the susceptor 107, 307, 407. The induction coil 111, 311, 411 remains “on” during the deposition process.

While the susceptor 107, 307, 407 material heats quickly, the temperature of the base 109 does not substantially increase when subjected to the induced electromagnetic field. The insulator material of the base 109, 309, 409 preferably has a high specific resistivity in the range of about 10¹⁰ Ω-cm to about 10¹³ Ω-cm which prevents substantial heating in the base 109, 309, 409 that may cause the temperature of the trap housing 101, 301, 401 to increase.

When the precursor gas comes into contact with the heated susceptor 107, 307, 407, the precursor gas molecules radicalize so that one portion of the molecule deposits on the surface while the other portion is left in the gaseous phase. For example, in the case where trimethylaluminum (Al(CH₃)₃) is present in the exhaust stream, aluminum (Al) will deposit on the heated susceptor 107, 307, 407 while gaseous compounds such as CH₄ and H₂, formed in the decomposition process, leave the susceptor surface. These gases are harmless to the one or more pumps 115, 315, 415 and may be easily removed from the system.

The present invention as described above and shown provides an inductively heated trap for decomposing gases prior to entering a vacuum pump. It is anticipated that other embodiments and variations of the present invention will become readily apparent to the skilled artisan in light of the foregoing description, and it is intended that such embodiments and variations likewise be included within the scope of the invention as set forth in the following claims.

I/We claim:

1. An apparatus for treating an effluent gas from a process chamber prior to entering a vacuum pump comprising:
a housing wherein a portion of the housing comprises an insulator material;
an inlet conduit to transport the effluent gas from the process chamber to the housing;
an outlet conduit to transport treated effluent gas from the housing to the vacuum pump;
a susceptor positioned within the housing proximate the insulator material; and
an induction coil positioned externally to the housing proximate the insulator material.

2. The apparatus of claim 1 wherein the inlet conduit is positioned within the outlet conduit in an annular arrangement.

3. The apparatus of claim 1 wherein the susceptor comprises a material having a specific resistivity of between about 5×10⁻⁵Ω-cm and about 1×10⁻³Ω-cm.

4. The apparatus of claim 1 wherein the susceptor comprises a carbon material.

5. The apparatus of claim 4 wherein the carbon material comprises high density graphite.

6. The apparatus of claim 1 wherein the insulator material comprises a dielectric material.

7. The apparatus of claim 1 wherein the insulator material has a specific resistivity of between about 10¹⁰ Ω-cm and about 10¹³ Ω-cm.

8. The apparatus of claim 1 wherein the susceptor is of the same geometry as the induction coil.

9. The apparatus of claim 1 wherein the center axes of the induction coil, the susceptor and the inlet conduit are aligned.

10. The apparatus of claim 1 wherein the housing comprises a removable member.

11. The apparatus of claim 1 wherein the process chamber is a semiconductor process chamber.

12. The apparatus of claim 1 wherein the process chamber is an atomic layer deposition chamber.

13. The apparatus of claim 1 wherein the vacuum pump is a turbomolecular pump.

14. The apparatus of claim 1 wherein the outlet conduit is adapted to transport treated effluent gas from the housing to a plurality of vacuum pumps.

15. An apparatus for treating an effluent gas from a semiconductor process chamber prior to entering a vacuum pump comprising:
a housing having a sealing means wherein a portion of the housing comprises an insulator material;
an inlet conduit adapted to transport the effluent gas from the semiconductor process chamber to the housing;
an outlet conduit adapted to transport treated effluent gas from the housing to the vacuum pump;
a plurality of susceptors within the housing wherein at least one of the susceptors is positioned proximate the insulator material; and
an induction coil positioned externally to the housing proximate the insulator material.

16. The apparatus of claim 15 further comprising a bracket connected to the housing and supporting the susceptors.

17. The apparatus of claim 15 further comprising a susceptor positioning means.

18. The apparatus of claim 17 wherein the susceptor positioning means comprises a push rod.

19. The apparatus of claim 17 wherein the susceptor positioning means comprises a reciprocating rod mechanism.

20. The apparatus of claim 15 wherein the outlet conduit is adapted to transport treated effluent gas from the housing to a plurality of vacuum pumps.

21. The apparatus of claim 15 wherein at least one of the plurality of susceptors comprises a material having a specific resistivity of between about 5×10^{-5Ω-cm and about} 1×10⁻³Ω-cm.

22. A method of treating an effluent gas from a process chamber prior to entering a vacuum pump wherein a trap is positioned between the process chamber and the vacuum pump and an inlet conduit connects the process chamber to the trap and an outlet conduit connects the trap to the vacuum pump comprising:
activating the vacuum pump;
activating an induction coil to heat a susceptor positioned within the trap wherein the effluent gas exits the inlet conduit, contacts the heated susceptor and decomposes; and
exhausting byproducts of the decomposed gas through the outlet conduit.

23. The method of claim 22 further comprising the step of maintaining a predetermined conductance of the effluent gas through the inlet conduit.

24. The method of claim 23 further comprising the step of selecting the predetermined conductance to achieve plug flow of the effluent gas through the inlet conduit.

25. The method of claim 22 wherein the step of activating the induction coil further includes heating the susceptor to a temperature of between about 400° C. and about 600° C.

26. A method of treating an effluent gas from a process chamber comprising:
activating an induction coil associated with a trap connected to the process chamber to heat a susceptor positioned in the trap;
activating a vacuum pump connected to the process chamber through the trap to draw effluent gas from the process chamber into the trap;
contacting the susceptor with the effluent gas to decompose the effluent gas; and
exhausting byproducts of the decomposed effluent gas of the trap through the vacuum pump.
